(19) United States
(12) Patent Application Publication
(10) Pub. No.: US 2011/0269302 A1
(43) Pub. Date: Nov. 3, 2011

(54) METHOD OF FABRICATING A SEMICONDUCTOR DEVICE

(75) Inventors: Harish Bhaskaran, New Haven, CT (US); Mikael T. Bjoerk, Affoltern am Albis (CH); Michel Despont, Zurich (CH); Bernd W. Gotsmann, Horgen (CH); Heinz Schmid, Waedenswil (CH)

(73) Assignee: INTERNATIONAL BUSINESS MACHINES CORPORATION, Armonk, NY (US)

(21) Appl. No.: 13/083,057

(22) Filed: Apr. 8, 2011

(30) Foreign Application Priority Data
Apr. 28, 2010 (EP) 10161347.9

(51) Int. Cl. H01L 21/265

(52) U.S. Cl. 438/530; 257/E21.334

(57) ABSTRACT

The invention relates to a method of fabricating a semiconductor device. The method includes: providing a semiconductor substrate and locally heating the semiconductor substrate by using a heated tip structure. Locally heating the semiconductor substrate is carried out to locally modify the electrical properties of the semiconductor substrate. The semiconductor substrate can be implanted with dopants, so that locally heating step causes a local activation of the implanted dopants. Furthermore, the semiconductor substrate can be provided with a dopant layer, so that locally heating step causes dopants to diffuse into the semiconductor substrate.

### CROSS-REFERENCE TO RELATED APPLICATION

This application claims priority under 35 U.S.C. §119 from European Patent Application No. 10161347.9 filed Apr. 28, 2010, the entire contents of which are incorporated herein by reference.

### BACKGROUND OF THE INVENTION

1. Field of the Invention

The present invention generally relates to the field of semiconductor technology and, more particularly, to a method of making a semiconductor device.

2. Description of Related Art

One main demand of the semiconductor industry is the continuous power enhancement provided by increasingly faster integrated circuits which is interrelated to a miniaturization of electronic structures. To realize smaller dimensions of electronic structures, fabrication methods, devices, and tools are continuously improved. This trend, however, presents challenging issues.

An example is the doping of semiconductor structures which is carried out to modify electrical properties of a semiconductor. In scaling CMOS devices (complementary metal oxide semiconductor), however, the inability to define doping at high spatial resolution is an unsolved problem for the 22 nm node and beyond.

One limitation of defined doping (spatial confinement) is the attainable lithographic resolution, since conventional methods make use of traditional lithographic processes. A further limitation is due to a heat treatment step which is performed in order to either introduce dopants into a semiconductor or to activate the same (“annealing”). The temperatures applied in this step may lead to a significant dopant diffusion and therefore to a blurring of the doped regions, because the heat is typically applied uniformly to the entire semiconductor substrate or wafer, respectively. These limitations are associated with both mass fabrication and prototyping.

A further disadvantage of the heat treatment step is that the doped regions have to be defined before other processes like metallization processes are undertaken. This is because these steps or the respective materials are not compatible with the high temperatures applied in the heat treatment step.

Such issues are not only associated with doping methods, but also with other methods performed in order to modify electrical properties of a semiconductor. An example is a silicidation process, wherein heat is applied to cause diffusion and chemical reactions to form a silicide.

Concerning the fabrication of structures with small feature sizes, for example in the nanometer range, it is known to use devices with micro-probes that include a tip. As an example, U.S. Pat. No. 7,439,501 B2 describes the application of a heated probe tip in order to cause a portion of a substrate in contact with the probe tip to decompose. With respect to doping, U.S. Pat. No. 6,531,379 B2 describes the application of a probe tip in order to physically drive or tap dopants from a layer into a semiconductor substrate arranged underneath the layer. Furthermore, it is known to use a laser beam in order to selectively heat a substrate and to activate dopants (“laser annealing”).

### SUMMARY OF THE INVENTION

The present invention provides an improved method of making a semiconductor device. According to the present method, electrical properties of a semiconductor substrate are modified in a defined region by locally heating with a heated tip structure.

According to an embodiment of the invention, a method of making a semiconductor device includes providing a semiconductor substrate and locally heating the semiconductor substrate with a heated tip structure. Locally heating the semiconductor substrate is applied to locally modify the electrical properties of the semiconductor substrate.

Using a heated tip structure makes it possible to supply the heat in a defined or specific region of the semiconductor substrate, for example with a sub-lithographic spatial resolution in the order of 1 nm. As a consequence, the electrical properties or conductivity, respectively, of the semiconductor substrate (or of a layer of the same) can be modified in a defined region with such a spatial resolution, as well. The method therefore allows for fabrication of electronic or integrated circuit structures with high resolution and in particular without the use of a mask, where desired. Because the heat is only supplied in a defined region, temperature sensitive processes (e.g. a metallization process) can also be conducted beforehand. Concerning the local modification of electrical properties of the semiconductor substrate, this modification can be directly or indirectly caused by the defined application of heat with the heated tip structure.

Another embodiment of the invention includes implanting dopants into the semiconductor substrate. Locally heating causes a local activation of the implanted dopants. This embodiment makes possible a direct electrical patterning of the semiconductor substrate with high resolution. In contrast to the above mentioned laser annealing, supplying eat with the heated tip structure can provide a higher spatial resolution, which can e.g. be improved by an order of magnitude or more.

Another embodiment of the invention includes applying a dopant layer containing dopants on the semiconductor substrate. Locally heating causes a local diffusion of dopants from the dopant layer into the semiconductor substrate. In this way, the electrical properties of the semiconductor substrate can be directly modified with high resolution. After the local heating step, the dopant layer can be removed from the semiconductor substrate.

The dopant layer can be an elemental for dopant layer. Alternatively, the dopant layer can also be a spin-on-dopant layer which can be applied to the semiconductor substrate with a spin-coating process.

For the semiconductor substrate having a dopant layer, local heating causes chemically modification the dopant layer in a defined region. In this embodiment, a chemically non-modified portion of the dopant layer can be removed from the semiconductor substrate, and a second heating step is applied to cause a further diffusion of dopants from the chemically modified region of the dopant layer into the semiconductor substrate. Also, locally heating with the heated tip structure is used to “indirectly” modify the electrical properties of the semiconductor substrate with high resolution. During this procedure, the locally heating step for chemically modifying the dopant layer can be conducted with a lower temperature than the second heating step to cause further diffusion of the dopants into the semiconductor substrate.

The further heating step can be a global heating step which is performed by heating the whole semiconductor substrate. Alternatively, the further heating step can also be performed locally with the heated tip structure.

According to another embodiment of the invention, the dopant layer (which is to be modified in a defined region) includes a polymer material. By heating the defined region of the semiconductor substrate, chemically modifying the dopant layer results in cross-linking or hardening of the polymer material, respectively.

Another embodiment of the invention includes a metallic layer on the semiconductor substrate. Locally heating causes a local silicidation of the semiconductor substrate. In this way, the electrical properties of the semiconductor substrate can be directly modified with high resolution as well. After the local heating step, the metallic layer can be removed from the semiconductor substrate.

The method is not restricted to an unstructured semiconductor substrate or substrate having a plane surface. According to another embodiment of the invention, the semiconductor substrate includes a structure element. Locally heating the semiconductor substrate is carried out in order to modify the electrical properties of at least a portion of the structure element of the semiconductor substrate. In this embodiment, the structure element of the semiconductor substrate can lead to a confinement of the heat applied with the tip structure, so that the modification of electrical properties can be locally restricted to the structure element or a portion of the same, respectively.

The structure element can protrude from the surface of the semiconductor substrate. Alternatively, the structure element can be embedded in the semiconductor substrate. An example for such a protruding or embedded structure element is a nanowire.

With respect to the heated tip structure, different configurations can be considered. According to another embodiment of the invention, the tip structure is arranged on a cantilever. The cantilever can be part of a scanning probe microscope, e.g. an atomic force microscope (AFM). Such a microscope can also be used to scan the surface of the semiconductor substrate in order to identify alignment marks.

According to another embodiment of the invention, the cantilever further includes an integrated heater. The heatable tip structure can be heated with the integrated heater.

According to another embodiment of the invention, the tip structure is arranged on a plate. At this, the tip structure is simply heated by heating the plate.

According to another embodiment of the invention, a number of defined regions are simultaneously heated by a plurality of heated tip structures. This can be carried out with a cantilever array including a plurality of cantilevers and the tip structures being arranged on each of the cantilevers. Alternatively, a plate including a plurality of tip structures can be used. In this alternative, heating up all of the tip structures can simply be conducted by heating the whole plate.

With respect to the application of such a plate, it is possible that the plate includes at least a first tip structure and a second tip structure, the first and second tip structure having a different shape. A single heating step can be performed in order to locally modify the electrical properties of the semiconductor substrate in different regions, where the different regions have their own shape and geometry.

### BRIEF DESCRIPTION OF THE DRAWINGS

FIG. 1 shows a flowchart of a fabrication of a semiconductor device according to an embodiment of the present invention.

FIGS. 2 to 4 schematically show a substrate illustrating a local activation of dopants according to an embodiment of the present invention.

FIGS. 5 to 8 schematically show a substrate illustrating a local diffusion of dopants and a local silicidation according to an embodiment of the present invention.

FIGS. 9 to 13 schematically show a substrate illustrating another local diffusion of dopants with a “two step” process according to an embodiment of the present invention.

FIG. 14 schematically shows a fabrication device which can be used for the simultaneous transfer of heat to a plurality of defined substrate regions according to an embodiment of the present invention.

FIG. 15 schematically shows a sectional view of the fabrication device of FIG. 14 according to an embodiment of the present invention.

Like reference numerals designate the same, similar, or corresponding features or functions throughout the drawings.

### DETAILED DESCRIPTION OF THE EMBODIMENT OF THE INVENTIONS

FIG. 1 shows a flow chart of method steps carried out in the fabrication of a semiconductor device. Step 101 provides a semiconductor substrate including a semiconductor substrate. The semiconductor substrate can be a conventional wafer which includes a semiconductive material such as silicon. It is also possible that the semiconductor substrate is a layered substrate. Furthermore, the semiconductor substrate can be (globally) doped, or can be covered with a layer, e.g. a dopant layer or a metallic layer, as described in detail further below.

In step 102, the semiconductor substrate is locally heated with a heatable tip structure. The local heating step 102 is carried out in order to locally modify the electrical properties or the conductivity of the semiconductor substrate in a defined region, thereby providing electronic or (integrated) circuit structures. The modification of the electrical properties can be directly caused by the defined application of heat with the heated tip structure. Alternatively, it is possible that the local heating is used indirectly to locally modify the semiconductor substrate's electrical properties.

The tip structure can be arranged on a cantilever which is part of a scanning probe microscope. Using this tip structure makes it possible to supply heat in a defined or specific region of the semiconductor substrate with precision due to high resolution. Particularly, a sub-lithographic resolution can be achieved. At this, the tip structure can be brought into physical contact with the semiconductor substrate, or can alternatively be located near or close to the semiconductor substrate.

Afterwards, processes can be carried out which are summarized in a step 103 in the flow chart of FIG. 1. These further processes can relate to the production of other electronic or (integrated) circuit structures, and can include a photolithography structuring method, a metallization process, a wafer dicing process in order to provide separate dies, etc. Concerning the above mentioned indirect connection between local heating and local modification of electrical properties of the semiconductor substrate, the step 103 can also include a further heating step.

Due to the local application of heat with the heated tip structure, the method steps 101, 102, 103 of FIG. 1 allow for fabrication of electronic structures with high resolution and in particular without the use of a mask, where desired. As an example, a spatial resolution in the order of 1 nm can be realized for the electronic structures. Because the heat is only supplied in a defined region, a large scale influence or change to the material structure of the whole substrate is avoided. This makes it possible to conduct temperature sensitive processes or processes including the application of temperature sensitive materials (e.g. a metallization process) beforehand. As a consequence, fabrication of a semiconductor device can be carried out with steps in a different or interchanged order, compared to a conventional fabrication scheme.

Embodiments illustrating the flowchart of FIG. 1 are described with respect to the following figures.

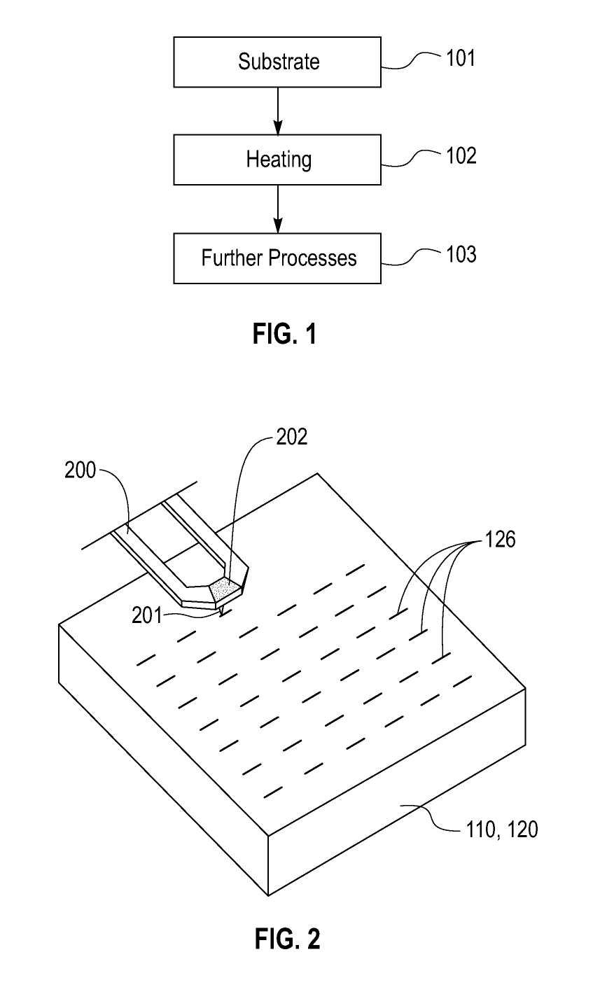

FIG. 2 shows a schematic perspective illustration of a provided semiconductor substrate 120 including a semiconductor substrate 110, the semiconductor substrate 110 including dopants being implanted into the semiconductor substrate 110 (not shown). The semiconductor substrate 110 can be a silicon wafer. It is also possible that the semiconductor substrate 110 is a so-called SOI-wafer, i.e. a layered silicon-insulator-silicon substrate, or a substrate including another layered structure. In this connection, it is intended to carry out a local modification of electrical properties in a surface region of a top or upper semiconductor (silicon) layer or material, respectively.

With respect to the implanted dopants, materials like As, B, P, Ga and In can be considered. The respective dopants can be introduced into the semiconductor substrate 110 with an ion implantation process. At this, the dopants can be globally implanted into the whole semiconductor substrate 110, or alternatively in a partial or large area of the substrate 110. Subsequent to the ion implantation, an annealing process is carried out in order to activate the implanted dopants, thereby directly modifying electrical properties of the semiconductor substrate 110. Here, the dopants are being effectively activated in well defined local regions and in high spatial resolution.

As further shown in FIG. 2, the local and selective activation can be carried out with a nanoscale tip structure or tip 201 being arranged on a cantilever 200, which is e.g. U-shaped. The cantilever 200 can be a component of a thermomechanical probe of a scanning probe microscope, an AFM microscope. In this connection, the scanning probe microscope can also be used to scan or image the substrate surface, in order to identify certain structures or alignment marks.

The cantilever 200 further includes an integrated heater 202, a heat resistor, which generates heat when an electric current passes through it. For this purpose, the electric current can be provided to the heater 202 with respective conductor paths arranged on or being integrated in the cantilever 200, respectively (not shown). With the integrated heater 202, the probe tip 201 can be heated, which can be used to further locally heat and anneal the semiconductor substrate 110, thereby locally and selectively activating the implanted dopants. For example, FIG. 2 shows a number of activated regions 126 in the form of thin lines. Instead of line structures, other structures or “electrical patterns” can also be formed with the heated tip 201.

The probe tip 201 can be fabricated with high fidelity down to a few nanometers or even below. Possible improvements of these exemplary dimensions can be realized, as well, by providing the tip 201 in the form of a nanotube or nanowire. The (lateral) dimensions of the tip 201 also define the dimensions of the heated regions on the surface of the substrate 110, and therefore of the selectively activated regions 126. In contrast to laser annealing, supplying heat with the heated tip 201 can provide a higher spatial resolution, which can e.g. be improved by an order of magnitude or more.

With respect to locally heating the substrate 110, different procedures can be considered. It is possible to bring the tip 201 and the surface of the semiconductor substrate 110 into physical contact with each other, and to subsequently heat the tip 201 with the heater 202, wherein the heat is transferred to the substrate 110 with thermal conduction (see FIG. 4). The tip 201 can be heated for a time period of a few seconds. At this, the tip 201 and therefore the substrate 110 can be heated to a temperature of several hundred or even above thousand degrees Celsius. Afterwards, the tip 201 and the substrate 110 can be released or disposed at a distance, the relative position of the tip 201 and the substrate 110 can be changed, and the tip 201 and the substrate 110 can be brought into contact again for a further local heat treatment. These steps can be repeated, in order to create one of the regions 126 in the form of a line structure as shown in FIG. 2. Alternatively, the tip 201 can already be heated before establishing a contact between the tip 201 and the substrate 110. Furthermore, it is also possible to only bring the tip 201 or keep the tip 201 (which can e.g. be laterally moved) near the surface of the substrate 110, without establishing a physical between these components. Concerning such a procedure, heat is transferred from the tip 201 to the substrate 110 with thermal radiation. It is pointed out that the above procedures are to be considered as illustrative examples only which can be exchanged by other procedures, as well.

FIG. 2 illustrates the semiconductor substrate 110 having a plane surface. However, the semiconductor substrate 120 including the semiconductor substrate 110 can also be provided in such a way that the (doped) semiconductor substrate 110 includes one or several structure elements. At this, the heated tip 201 can be used to modify the electrical properties of the structure elements or of a portion thereof, respectively, as well.

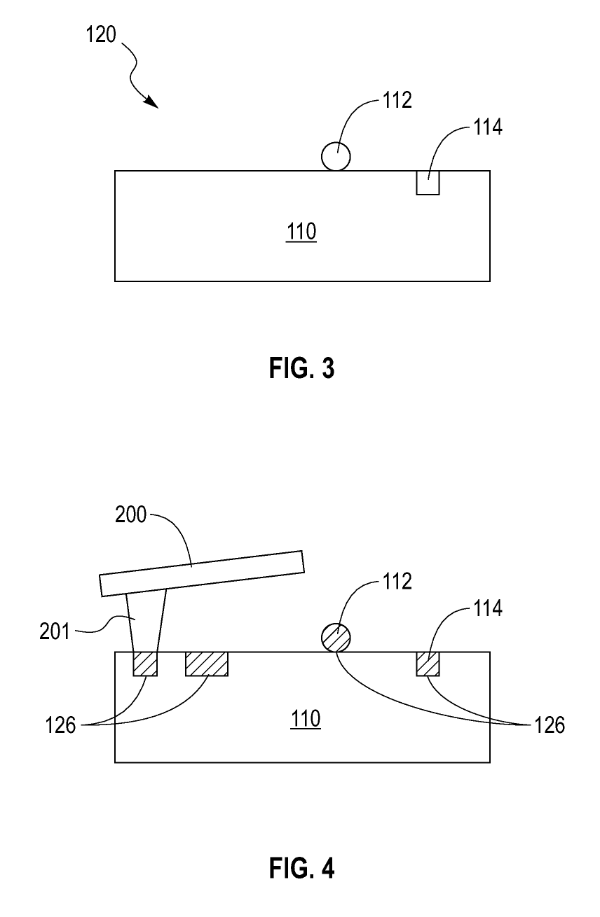

For way of illustration, FIG. 3 shows a schematic cross-sectional view of the semiconductor substrate 110, which includes two nanostructures or structure elements 112, 114. Here, the structure element 112 is arranged on the surface of the substrate 110 and protrudes from the same, whereas the structure element 114 is an embedded structure element being exposed at the substrate surface. Each of the structure elements 112, 114 can be a nanowire. Potential materials for the structure elements 112, 114 can include a semiconductor material (silicon), or a III-V semiconductor material (GaAs, InAs, InP, etc).

Concerning the above mentioned ion implantation process; this process is carried out after the formation of the structure elements 112 and 114, so that the structure elements 112, 114 can also include dopants. Consequently, as shown in the cross-sectional illustration of FIG. 4, the heated tip 201 arranged on the cantilever 200 can be used to activate dopants being implanted into the actual substrate 110, and also be used to activate dopants being implanted into the structure elements 112 and 114. In other words, the structure elements 112, 114 (or a portion thereof) can likewise be converted into selectively activated regions 126, as indicated in FIG. 4.

Furthermore, the heat applied with the micro-tip 201 to the structure elements 112, 114 can be locally confined to the same, in particular for the case that the structure elements 112, 114 include a different semiconductor material compared to actual substrate 110. Consequently, the modification of electrical properties by dopant activation can be locally restricted to the structure elements 112, 114, and a (undesired) modification of electrical properties of substrate material close to the structure elements 112, 114 (i.e. underneath the structure element 112 or surrounding the structure element 114) can be avoided. In order to transfer heat from the tip 201 to the structure elements 112, 114, the tip 201 can be in physical contact with the structure elements 112, 114, or can alternatively be disposed close to the same.

In the following, further methods are described in which a local modification of electric properties is similarly carried out by the supply of heat with a tip structure. With respect to details concerning corresponding features, possible benefits, effects, devices for carrying out process steps etc., reference is made to the above description.

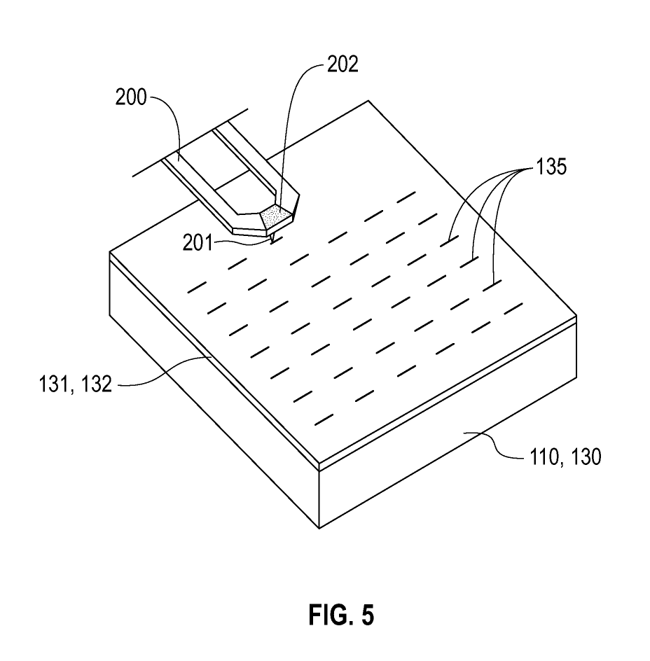

FIG. 5 shows a schematic perspective illustration of a provided semiconductor substrate 130 including a semiconductor substrate 110 which is coated with a dopant layer 131 including dopants. If desired, the dopant layer 131 can be patterned (not shown). The semiconductor substrate 110 can be silicon or another (e.g. layered) wafer. With respect to the dopant layer 131, dopants like As, B, P, Ga and In can be considered. At this, the dopant layer 131 can include or can be composed of the respective dopant in elemental form. Alternatively, the dopant layer 131 can also be a spin-on-dopant layer including different materials including the respective dopant which can easily be applied to the surface of the semiconductor substrate 110 with a spin-coating process. An example is a spin-on-glass (SOG) including dopants.

Subsequent to the formation of the dopant layer 131 on the surface of the semiconductor substrate 110 (with or without patterning), an annealing process is carried out in order to diffuse dopants from the dopant layer 131 into the semiconductor substrate 110, thereby directly modifying the electrical properties of the same. Here, a selective diffusion of dopants is carried out in very defined regions and with high resolution.

As depicted in FIG. 5, the local and selective diffusion of dopants can (again) be carried out with a heated nanoscale tip structure 201 arranged on a U-shaped cantilever 200, the cantilever including an integrated heater 202. The heated tip 201 can be used to selectively supply heat to the dopant layer 131. For way of illustration, FIG. 5 indicates heated regions 135 in the form of thin lines, wherein dopants are locally “driven” into the semiconductor substrate 110 in these regions 135. At this, the heated tip 201 can be brought into contact with the surface of the dopant layer 131 in the area where the dopants are to be diffused. The tip 201 can be heated for a time period of a few seconds. Because the heat is applied locally, a doping of the semiconductor substrate 110 substantially only occurs in that region. Instead of establishing a physical contact, the tip 201 and the dopant layer 131 can also be arranged close to each other.

FIG. 5 illustrates the semiconductor substrate 110 having a plane surface. However, the semiconductor substrate 130 including the (coated) semiconductor substrate 110 can also be provided in such a way that the semiconductor substrate 110 includes one or several structure elements. At this, the heated tip 201 can be used to modify the electrical properties of the structure elements or of a portion thereof, respectively, as well.

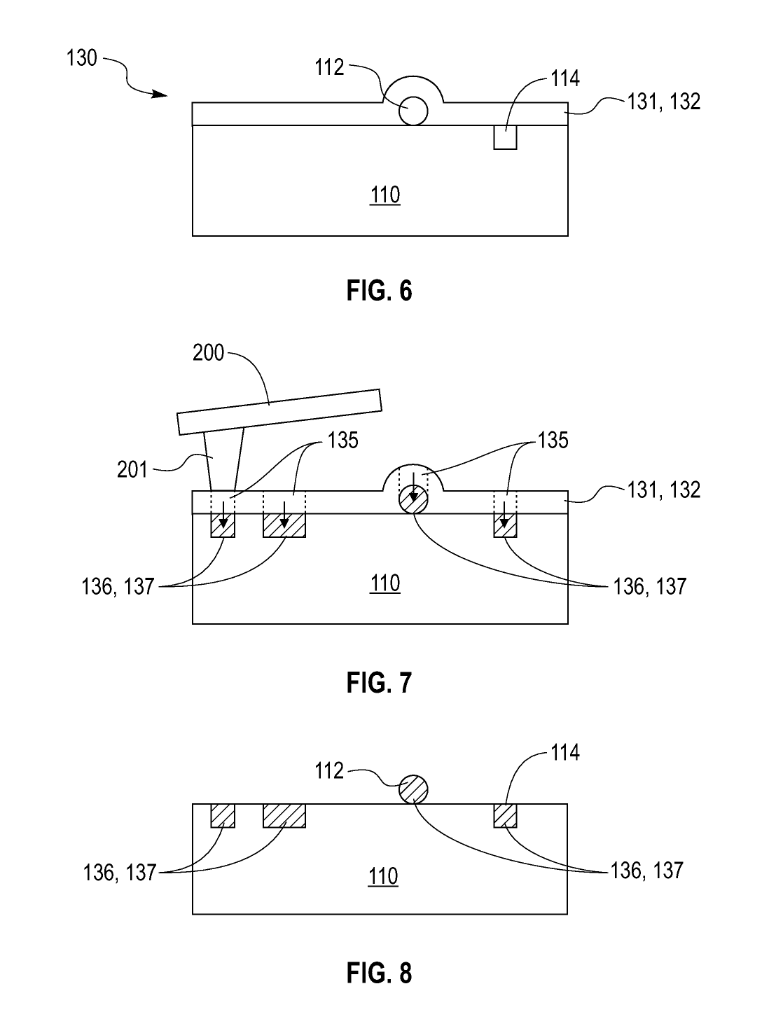

For way of illustration, FIG. 6 shows a schematic cross-sectional view of the semiconductor substrate 110, which includes the (above described) two nanostructures or structure elements 112, 114. In this case, the applied dopant layer 131 covers the structure elements 112, 114.

As further shown in the cross-sectional illustration of FIG. 7, the heated tip 201 arranged on the cantilever 200 can be used to supply heat to the dopant layer 131 in regions 135 which are also close to or above the structure elements 112, 114. As indicated by arrows, local diffusion of dopants occurs in the heated regions 135, whereby doped regions 136 are being formed. At this, not only sections of the actual substrate 110 can be “converted” into doped regions 136, but also the structure elements 112, 114 (or a portion thereof). The heat applied with the tip 201 in the area of the structure elements 112, 114 can be locally confined to the same, so that a (not intended) doping or modification of electrical properties of substrate material close to the structure elements 112, 114 can be avoided.

After forming the doped regions 136 with the selective heat treatment, the dopant layer 131 can be removed from the semiconductor substrate 110, as shown in FIG. 8.

The heat-driven dopant diffusion can also be carried out in such a way that a number or multiple different dopants are selectively introduced into the semiconductor substrate 110. In this respect, the dopant layer 131 can include different dopant types. It is also possible to form the dopant layer 131 in such a way that different layers or sublayers are successively provided on the substrate 110, each sublayer including a different dopant type. In this connection, each of the sublayers can be a respective spin-on-dopant.

The lateral resolution of electronic structures which are attainable with the local dopant diffusion is limited by the diffusion length of the dopants and the size of a mechanical contact between the layer 131 and the tip structure 201, or the diameter of the tip structure 201, respectively. As described above, a nanostructure embedded into or put onto the substrate surface can lead to a (further) confinement of the locally applied heat.

The selective heat treatment using the heated tip structure 201 can also be used for a local silicidation of the semiconductor substrate 110, thereby enabling a direct modification of the electrical properties of the semiconductor substrate 110 with high resolution, as well. Such a procedure is again described with reference to FIGS. 5 to 8.

In this respect, the provided semiconductor substrate 130 depicted in FIGS. 5 and 6 includes the semiconductor substrate 110 which is coated with a metallic layer 132 (instead of the dopant layer 131). The metallic layer 132 can include Cu, Pt or Ni. It is also possible that the layer 132 includes sublayers of different metallic materials. Furthermore, the substrate 110 can (again) include the (above described) two nanostructures or structure elements 112, 114. In this case, the metallic layer 132 covers the structure elements 112, 114, as shown in FIG. 6.

Subsequent to the formation of the metallic layer 132 (which can also be patterned, if required) on the surface of the semiconductor substrate 110 and on the structure elements 112, 114, respectively, the heated tip 201 can be used to selectively supply heat to the metallic layer 132, e.g. in the regions 135 as shown in FIGS. 5 and 7. As a consequence, a local diffusion of metallic components or atoms from the metallic layer 132 into the semiconductor substrate 110 and into the structure elements 112, 114 can be caused in the area of the heated regions 135, and silicided regions 137 can be selectively formed, as indicated in FIG. 7. At this, also the structure elements 112, 114 (or a portion thereof) can be “converted” into silicided regions 137. The heat applied with the tip 201 in the area of the structure elements 112, 114 can be locally confined to the same, so that a (not intended) silicidation and therefore modification of electrical properties of substrate material close to the structure elements 112, 114 can be avoided.

Concerning the application of heat, the tip 201 can be brought into physical contact with the surface of the metallic layer 132 in the area where the localized silicidation is to be caused. In contrast to the above described local diffusion of dopants, the tip 201 can be heated for a relatively short time period, which is under a millisecond, or even below a microsecond. Instead of establishing a physical contact, the tip 201 and the metallic layer 132 can also be arranged close to each other.

After forming the silicided regions 137 with the selective heat treatment, the metallic layer 132 can be removed from the semiconductor substrate 110, as shown in FIG. 8.

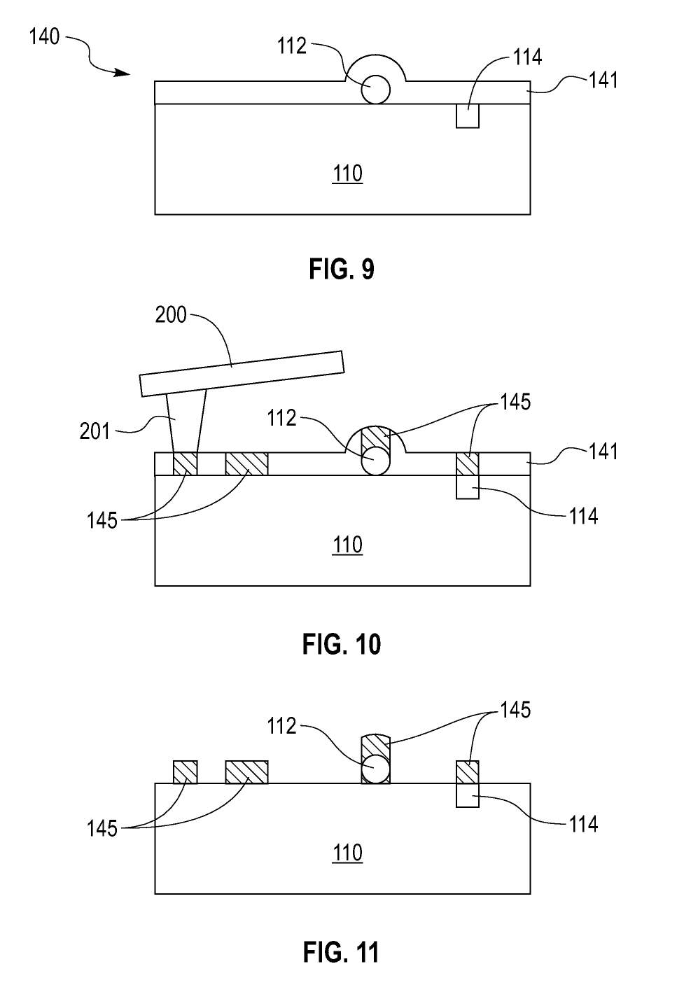

The local application of heat with a tip structure 201 can also be carried in order to modify electrical properties of a semiconductor substrate 110 with high resolution in an “indirect” manner. An exemplary procedure is described below with reference to the FIGS. 9 to 13.

FIG. 9 shows a schematic cross-sectional illustration of a provided semiconductor substrate 140 including a semiconductor substrate 110 (for example, a silicon or another e.g. layered wafer) which is coated with a dopant layer 141 including a dopant (e.g. As, B, P, Ga or In). If desired, the dopant layer 141 can be patterned (not shown). The semiconductor substrate 110 (again) includes the exemplary two structure elements 112, 114, which are also covered by the dopant layer 141.

The dopant layer 141 includes, in addition to the dopants, a material which can be chemically modified (in particular modification of the solubility) by the application of heat. Such a material can in particular be a polymer material, so that chemically modifying can be effected by a cross-linking reaction of the polymer material. In this connection, the layer 141 can be a spin-on doping polymer layer, which is applied to the surface of the semiconductor substrate 110 with a spin-coating process.

Next, a nanoscale tip 201 arranged on a cantilever 200 (which can include an integrated heater) can be used in order to selectively transfer heat into the layer 141. This local rise of temperature leads to a prebaking that results in cross-linking or hardening, respectively, of the polymer layer 141, thereby forming hardened regions 145 (“crust”), as shown in FIG. 10. Here, locally heating can be performed in areas of the substrate 110 with a distance to the structure elements 112, 114, and close to or above the structure elements 112, 114.

Concerning the application of heat, the tip 201 can be brought into physical contact with the surface of the layer 141 in the area where the localized hardening is to be caused, and the tip 201 can be heated for a given amount of time. At this, the tip 201 can be heated to a relatively low temperature (compared to a temperature applied for dopant diffusion), which can be around or below two hundred degree Celsius. The provision of the structure elements 112, 114 can lead to a confinement of the heat applied with the tip and therefore to a spatial confinement of the respective regions 145. Instead of establishing a physical contact, the tip 201 and the layer 141 can also be arranged close to each other.

In a next step, the non-hardened or “unexposed” portion of the polymer layer 141, that has not turned into a crust is removed from the semiconductor substrate 110, as shown in FIG. 11. This can be carried out by using of an appropriate solvent. The removal result can be checked with the scanning probe microscope or AFM microscope including the cantilever 200 with the tip 201. In this connection, the microscope is operated in an imaging mode.

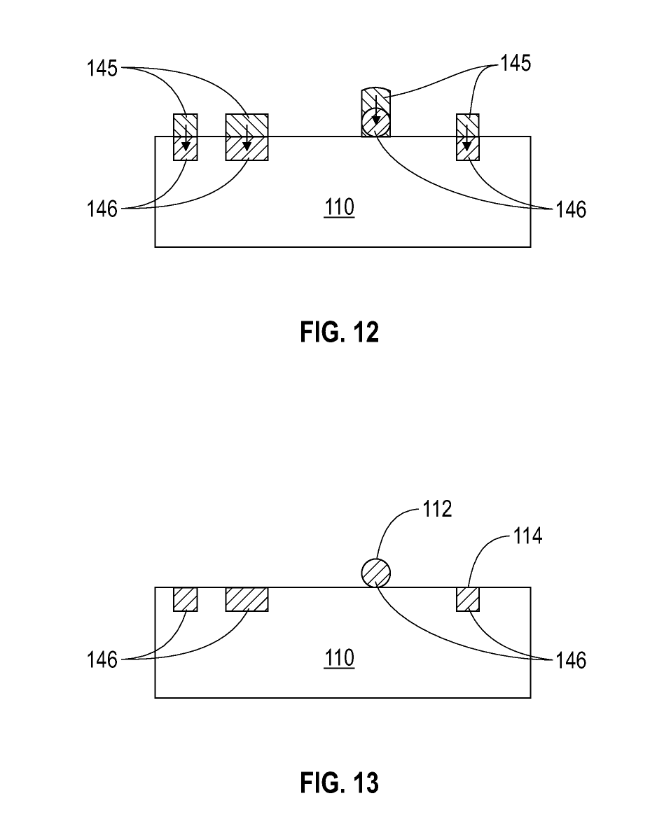

Subsequently, a further heating step is carried out in order to cause a local diffusion of dopants from the hardened regions 145 of the layer 141 into the semiconductor substrate 110 and the structure elements 112, 114, thereby producing doped regions 146, as shown in FIG. 12. This anneal step can be performed locally, by using the heated tip 201, or alternatively by irradiating the hardened regions 145 with a laser beam. Furthermore, diffusion of dopants from the hardened regions 145 can also be performed with a global heating step, wherein the entire substrate 110 is heated. Compared to the above described preceding (or first) heating step carried out for locally hardening the dopant layer 141, the further (or second) heating step for dopant diffusion can imply a higher temperature, which can be around eight hundred degree Celsius.

After forming the doped regions 146, the remaining crust can be removed from the semiconductor substrate 110, as shown in FIG. 13.

The lateral resolution of electronic structures which are attainable with this indirect “two step” process is limited by the diffusion length and the size of the patterned regions 145. The latter can be dependent on the size of a mechanical contact between the layer 141 and the tip structure 201, or of the diameter of the tip structure 201, respectively. As described above, a nanostructure embedded into or put onto the substrate surface can lead to a (further) confinement of the locally applied heat.

With respect to the above described methods, a single tip 201 being arranged on a cantilever 200 can be used in order to selectively supply heat to a semiconductor substrate. Instead of this, it is also possible to simultaneously heat a number of defined regions or areas by a number of heatable tip structures 201 being arranged on cantilevers, the cantilevers being configured in the form of a cantilever array (not shown). Moreover, instead of the application of tips being arranged on cantilevers, other devices having one or a plurality of micro-tips can be employed for the localized application of heat.

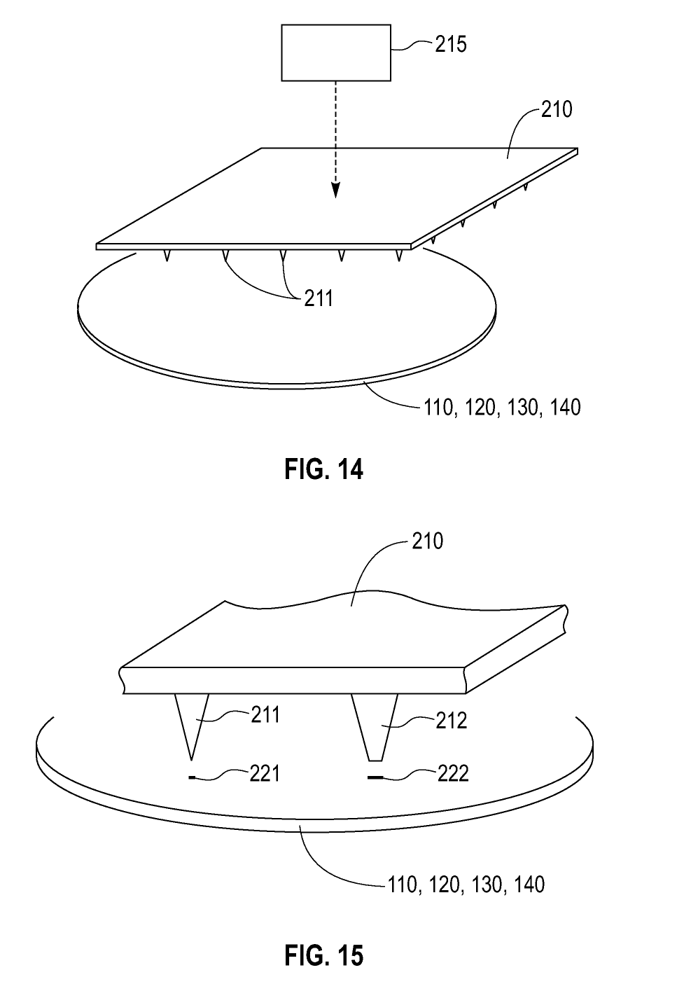

For way of illustration, FIG. 14 shows a fabrication device or tool which can be used for the simultaneous application of heat to a plurality of defined substrate regions of a semiconductor substrate, which is one of the above described semiconductor substrates 120, 130, 140 including the semiconductor substrate 110. The device includes a base component in the form of a plate 210. The plate 210, which preferably includes a material with a high thermal conductivity, further includes a plurality of nanoscale tips 211. The tips 211, which are arranged on a surface of the plate and protrude from the same, can be of any defined shape. At this, the plate 210 with the tips 211 can be configured similarly to an embossing or imprint plate or template, respectively.

The device furthermore includes a heating device 215 which is configured to heat the whole plate 210. In this way, all off the tips 211 can be heated simultaneously and in an easy way. Consequently, the tips 211 which are in physical contact with a substrate structure can simultaneously transfer the heat to defined regions of the substrate structure, e.g. in order to cause a diffusion of dopants similar to FIG. 7 (“batch diffusion”).

Instead of a heating device 215 for heating the whole template 210, the fabrication device depicted in FIG. 14 can also provided with a plurality of integrated heaters, which are arranged at or close to the respective tips 211. In this way, the tips 211 can individually be heated.

With respect to the application of a fabrication device including a plate 210, it is possible that the plate 210 includes tip structures having different shapes. As an example, FIG. 15 shows an enlarged schematic sectional view of the plate 210 including two tip structures 211, 212 having different shapes. At this, the tip structure 211 has a more pointy or tapered shape compared to the tip structure 212. The tip structure 211 can heat the respective substrate or semiconductor substrate 110, 120, 130, 140 e.g. in a punctual region 221, whereas the tip structure 212 can heat the substrate or semiconductor substrate 110, 120, 130, 140 in a region 222 having e.g. the shape of a thin line.

The application of tip structures 211, 212 having different shapes or geometries makes it possible to perform a single heating step in order to locally modify the electrical properties of the respective substrate in different regions 221, 222, the different regions 221, 222 having an individual (lateral) shape or geometry. Instead of the depicted tips 211, 212, other tips having different shapes can also be provided, thereby allowing for the transfer of heat in local regions having a different or more complex geometry, respectively. Furthermore, instead of (only) two different geometries or shapes for the tip structures 211, 212, the plate 210 can also be provided with a larger number of different geometries or shapes for the tip structures.

The embodiments described in conjunction with the drawings are examples. Moreover, further embodiments can be realized which include further modifications. As an example, the mentioned specifications concerning potential materials, time periods, applied temperatures, dimensions etc. are to be considered as examples only, which can be exchanged by other specifications. It is possible to use a semiconductor substrate, which is based or which includes other semiconductor materials than silicon, a III-V semiconductor material such as GaAs, InAs, and InP.

Moreover, further process and fabrications steps can be carried out in addition to the mentioned method steps. Such processes can be carried out before or after the selective heat treatment, and can include other forms of patterning (“mix and match lithography”).

As an example, a substrate provided (step 101 of FIG. 1) for a selective heat treatment with a heated tip can already include (other) electronic or circuit structures, which are produced by carrying out respective processes beforehand. It is also possible that a provided substrate includes a structured or patterned surface or surface layer, respectively, which is to be subjected to the selective heat treatment in order to locally change electrical properties. Furthermore, the above described steps can also be repeated, to allow for a repair step.

Concerning the depicted structure elements 112, 114 having a circular or rectangular cross-section, it is possible to provide similar structure elements which have a different shape. Furthermore, it is possible to provide no structure element or a different number of structure elements on a substrate instead of the depicted two structure elements 112, 114. It is also possible to provide only protruding or only embedded structure elements on a substrate.

With respect to the depicted U-shaped cantilevers 200, it is possible to use cantilevers with heatable tips having a different shape. An example is a cantilever having a strip-like form. Furthermore, heating a tip which is arranged on a cantilever can be carried out in a different way compared to using an integrated heater of a cantilever. As an example, a laser beam can irradiated on a front end of a cantilever in order to heat up a tip structure being arranged in this area of the cantilever. Furthermore, concerning the simultaneous heat treatment with tips being arranged on cantilevers of a cantilever array, such tips can also include different (e.g. two or more different) shapes. For further details, reference is made to the above description of FIG. 15.

Modifications can also be considered with respect to a dopant layer, for example the dopant layer 131 depicted in FIGS. 5 to 7. Instead of the mentioned layer 131 including dopants in elemental form or being a spin-on-dopant layer, other material mixtures or blends including dopants can be considered, which can be applied on a substrate with other processes.

With regard to the indirect method described in conjunction with FIGS. 9 to 13, it is possible to diffuse multiple different dopants into the substrate 110. In this case, layers or sublayers (e.g. polymer layers) including different dopant types can be formed on the respective substrate, wherein a local heat treatment results in local hardening of the same.

While the present invention has been described with reference to what are presently considered to be the embodiment of the inventions, it is to be understood that the present invention is not limited to the disclosed embodiments. On the contrary, the present invention is intended to cover various modifications and equivalent arrangements included within the spirit and scope of the appended claims. The scope of the following claims is to be accorded the broadest interpretation so as to encompass all such modifications and equivalent structures and functions.

1. A method of making a semiconductor device, comprising:
providing a semiconductor substrate; and
locally heating said semiconductor substrate with a heated tip structure, so that electrical properties of said semiconductor substrate is locally modified.

2. The method according to claim 1, further comprising:
implanting dopants into said semiconductor substrate, so that said locally heating step causes a local activation of said implanted dopants.

3. The method according to claim 1, further comprising:
applying a dopant layer comprising dopants on said semiconductor substrate, so that said locally heating step causes a local diffusion of dopants from said dopant layer into said semiconductor substrate.

4. The method according to claim 3, wherein said dopant layer is a layer selected from the group consisting of an elemental form dopant layer and a spin-on-dopant layer.

5. The method according to claim 3, wherein said locally heating step causes a chemical modification of said dopant layer in a defined region.

6. The method according to claim 5, further comprising:
removing a chemically non-modified portion of said dopant layer from said semiconductor substrate; and
carrying out a second heating step to cause a further diffusion of dopants from said chemically modified region of the dopant layer into said semiconductor substrate.

7. The method according to claim 5, wherein said dopant layer is a polymer material, so that locally heating step on said chemically modified region causes cross-linking of said polymer material.

8. The method according to claim 6, wherein said second heating step is a locally heating step.

9. The method according to claim 6, wherein said second heating step is a global heating step.

10. The method according to claim 1, wherein said semiconductor substrate comprises a metallic layer on said semiconductor substrate, so that said locally heating step causes a local silicidation of said semiconductor substrate.

11. The method according to claim 1, wherein said semiconductor substrate comprises a structure element selected from a group consisting of a protruding structure element and an embedded structure element, so that said locally heating step modifies the electrical properties of at least a portion of said structure element of said semiconductor substrate.

12. The method according to claim 1, further comprising:
arranging said heated tip structure on a cantilever for locally heating said semiconductor substrate.

13. The method according to claim 12, wherein said cantilever comprises
an integrated heater, so that said heated tip structure is heated by said integrated heater.

14. The method according to claim 1, further comprising:
arranging said heated tip structure on a plate.

15. The method according to claim 14, wherein said heated tip structure is heated by heating said plate.

16. The method according to claim 14, wherein said plate comprises at least a first tip structure and a second tip structure.

17. The method according to claim 16, wherein said first tip structure and second tip structure have a different shape.

18. The method according to claim 1, further comprising:
simultaneously heating a number of defined regions of said semiconductor substrate with a plurality of said heated tip structures.
